(19) United States
(12) Patent Application Publication
(10) Pub. No.: US 2021/0272824 A1
(43) Pub. Date: Sep. 2, 2021

(54) APPARATUS FOR SIMULTANEOUSLY TRANSFERRING MICRO-DEVICES TO TARGET OBJECT

(71) Applicant: Ledaz Co., Ltd., Seongnam-si (KR)

(72) Inventors: Joong In An, Yongin-si (KR); Do Hwan Ahn, Seongnam-si (KR)

(21) Appl. No.: 17/255,395

(22) PCT Filed: Oct. 8, 2018
(86) PCT No.: PCT/KR2018/011843

§ 371 Date: Dec. 22, 2020

(30) Foreign Application Priority Data
Jun. 26, 2018 (KR) 10-2018-073591
Oct. 5, 2018 (KR) 10-2018-0119261

(51) Int. Cl. H01L 21/67; H01L 25/075; H01L 21/683; H01L 33/62

(52) U.S. Cl. CPC H01L 21/67144; H01L 25/0753; H01L 21/6835; H01L 2933/0066; H01L 2221/68354; H01L 2221/68368; H01L 33/62

(57) ABSTRACT

An apparatus for simultaneously transferring micro devices to a target object is disclosed. The apparatus may include a plurality of red, green, and blue micro devices adhered to a transfer sheet by an adhesive material, a target substrate to which the micro devices are transferred, an aligner configured to align the plurality of micro devices with the target substrate, and a laser beam emitter disposed above the transfer sheet and configured to emit beams having a specific wavelength in the direction passing through the transfer sheet. The micro devices each include a growth substrate, a first semiconductor layer and a second semiconductor layer disposed on the growth substrate, a first pad disposed on the first semiconductor layer and a second pad disposed on the second semiconductor layer, and an adhesive material disposed on the first pad and the second pad. When the micro devices and the target substrate have been aligned in transfer positions by the aligner, the laser beam emitter applies energy to the adhesive material so as to transfer the micro devices to the target substrate. Accordingly, transfer efficiency can be improved.

### RELATED APPLICATIONS

This application is a 371 national phase application of International Patent Application No. PCT/KR2018/011843, filed on Oct. 8, 2018, which claims priority to Korean Patent Application No. 10-2018-0073591, filed on Jun. 26, 2018 and Korean Patent Application No. 10-2018-0119261, filed on Oct. 5, 2018, the entirety of each of which is incorporated herein by reference.

### FIELD

The present disclosure relates to an apparatus for simultaneously transferring micro devices to a target object.

### BACKGROUND

Stamp transfer refers to a transfer in which an article to be transferred (for example, a micro device) is mounted on a substrate, and since the contact surface between the micro device and the substrate is flat, horizontal alignment of the two contacting surfaces is important, and the adhesive force between the micro device and a sheet is an important factor in transfer. That is, due to slight irregular horizontal contact or non-uniformity in the adhesive force in the sheet, the transfer yield may decrease.

Accordingly, when transferring micro devices to a substrate, a transfer method having excellent transfer efficiency is required. In addition, a transfer method for transferring to the substrate a large number of micro devices included in a large area is required.

The above information is only presented as background information to assist in understanding of the present disclosure. No decision has been made, and no argument is made, as to whether any of the above is applicable as prior art to the present disclosure

### SUMMARY

The present disclosure has been conceived to address the above-described issues, and an embodiment of the present disclosure is directed to providing an apparatus that performs large area transfer, for transferring individual micro devices or simultaneously transferring multiple micro devices to a target object.

Aspects of the present disclosure are not limited to what has been described above, and other aspects not mentioned above will be apparent from the following description to those skilled in the art to which the present disclosure pertains.

An apparatus for simultaneously transferring micro devices to a target object according to one embodiment of the present disclosure may include a plurality of red, green, and blue micro devices adhered to a transfer sheet by an adhesive material, a target substrate to which the micro devices are transferred, an aligner configured to align the plurality of micro devices with the target substrate, and a laser beam emitter disposed above the transfer sheet and configured to emit beams having a specific wavelength in the direction passing through the transfer sheet. The micro devices each include a growth substrate, a first semiconductor layer and a second semiconductor layer disposed on the growth substrate, a first pad disposed on the first semiconductor layer, a second pad disposed on the second semiconductor layer, and an adhesive material disposed on the first pad and the second pad. When the micro devices and the target substrate have been aligned in transfer positions by the aligner, the laser beam emitter applies energy to the adhesive material so as to transfer the micro devices to the target substrate.

More specifically, the adhesive material adhered to the first pad and the second pad of the micro devices is melted using beams having a specific wavelength that pass through all the micro devices, so as to transfer the micro devices to the target substrate.

More specifically, the adhesive material adhered to the first pad and the second pad of the plurality of green and blue micro devices device is melted using beams having a specific wavelength that pass through green and blue micro devices, and in the case of the red micro devices, the adhesive material around pads of the red micro devices is melted, so as to transfer the red micro devices to the target substrate.

More specifically, the apparatus further includes masks respectively disposed on the transfer sheet at regions aligned with the plurality of micro devices, wherein the beams of the laser beam emitter do not pass through the plurality of micro devices but melt the adhesive material around the first pad and the second pad of the plurality of micro devices so as to transfer the micro devices to the target substrate.

More specifically, the wavelength of the beams having a specific wavelength may be 1400 nm, and may be at least one of 915 nm, 950 nm, or 980 nm.

More specifically, an ambient temperature of a place where the apparatus is driven may be in a range of 150 degrees Celsius to 220 degrees Celsius.

More specifically, when the micro devices are arranged in a plurality of rows and a plurality of columns, the laser beam may move in a column direction while simultaneously transferring one row or a plurality of rows to the target substrate, from a first row to a last row.

In addition, the plurality of red, green, and blue micro devices may be disposed at regular intervals, and the plurality of red, green, and blue micro devices may be sequentially arranged in an order of red, green, and blue, or may be arranged in a random order.

An apparatus for simultaneously transferring micro devices to a target object according to another embodiment of the present disclosure may include a plurality of micro devices adhered to a transfer sheet by an adhesive material, a target substrate to which the micro devices are transferred, an aligner configured to align the plurality of micro devices with the target substrate, and a laser beam emitter disposed above the transfer sheet and configured to emit beams having a specific wavelength in the direction passing through the transfer sheet. The micro devices each include a growth substrate, a first semiconductor layer and a second semiconductor layer disposed on the growth substrate, a first pad disposed on the first semiconductor layer, a second pad disposed on the second semiconductor layer, and an adhesive material disposed on the first pad and the second pad. When the micro devices and the target substrate have been aligned in transfer positions by the aligner, the laser beam emitter applies energy to the adhesive material so as to transfer the micro devices to the target substrate. The plurality of micro devices may be composed of only one type among red micro devices, green micro devices, and blue micro devices.

An apparatus for simultaneously transferring micro devices to a target object according to another embodiment of the present disclosure may include a plurality of red, green, and blue micro devices adhered to a transfer sheet by an adhesive material, a target substrate, wherein the micro devices are transferred to one surface of the target substrate, an aligner configured to align the plurality of micro devices with the target substrate, and a laser beam emitter configured to emit beams having a specific wavelength in the direction passing through the transfer sheet from the other surface of the target substrate. The micro devices each include a growth substrate, a first semiconductor layer and a second semiconductor layer disposed on the growth substrate, a first pad disposed on the first semiconductor layer, a second pad disposed on the second semiconductor layer, and an adhesive material disposed on the first pad and the second pad. When the micro devices and the target substrate have been aligned in transfer positions by the aligner, the laser beam emitter applies energy to the adhesive material so as to transfer the micro devices to the target substrate.

According to embodiments of the present disclosure, a transfer yield may be increased by performing large area transfer.

In addition, apparatuses without any size limitation may be manufactured using the above-described apparatus and method. In particular, in accordance with the competitive release of large area displays in the field of televisions (TVs), applying the apparatus according to embodiments of the present disclosure can allow large area displays to be easily produced.

Effects that can be achieved by the present disclosure are not limited to what has been described above, and other effects not mentioned above will be apparent from the following description to those skilled in the art to which the present disclosure pertains.

### BRIEF DESCRIPTION OF THE DRAWINGS

The above and other aspects, features, and advantages of the present disclosure will become apparent from the detailed description of the following aspects in conjunction with the accompanying drawings, in which:

FIG. 1 is a block diagram illustrating components of an apparatus for simultaneously transferring micro devices to a target object according to an embodiment of the present disclosure.

FIG. 2 is a cross-sectional view illustrating the structure of the micro devices according to an embodiment of the present disclosure.

FIGS. 3 to 6 illustrate transfer methods of an apparatus for simultaneously transferring micro devices to a target object according to various embodiments of the present disclosure.

FIG. 7 shows transmittance of a laser beam with respect to gallium nitride (GaN).

FIG. 8 shows the transmittance of the laser beam with respect to gallium arsenide (GaAs).

### DETAILED DESCRIPTION

Hereinafter, preferred embodiments disclosed herein will be described in detail with reference to the accompanying drawings, in order to facilitate easy understanding of the configuration and effects of the present disclosure. In the interest of clarity, not all details of known functions or components are described in detail in the present specification if it is deemed that such details may unnecessarily obscure the gist of the present disclosure.

Prior to beginning the description with reference to the drawings, the term “micro device” as used herein may refer to a descriptive size of specific devices or structures according to the embodiments of the present disclosure. As used herein, “micro device” may be used to refer to structures or devices having dimensions on a scale of 1 μm to 500 μm. Specifically, the micro devices may have a width or length in the range of 1 to 50 microns, 50 to 500 microns, or 10 to 250 microns. The thickness of the micro devices is typically less than the width or length thereof. For example, the thickness of the micro devices may be less than 20 microns, less than 10 microns, or less than 5 microns. However, it is to be appreciated that the embodiments of the present disclosure are not necessarily limited as such, and that certain aspects of the embodiments may be applied at larger or smaller scale sizes. The micro devices may be a variety of devices. For example, the micro devices may include micro light emitting diodes (LEDs) or the like, but the embodiments are not limited thereto.

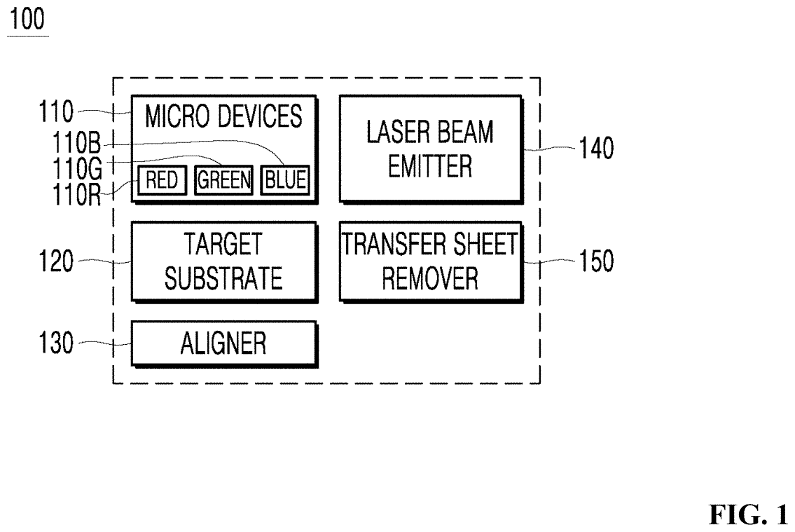

FIG. 1 is a block diagram illustrating components of an apparatus for simultaneously transferring micro devices to a target object (100; hereinafter referred to as a “transfer apparatus”) according to an embodiment of the present disclosure.

Referring to FIG. 1, the transfer apparatus 100 includes a plurality of micro devices 110, a target substrate 120, an aligner 130, a laser beam emitter 140, and a transfer sheet remover 150. Since the components shown in FIG. 1 are not essential for implementing the transfer apparatus 100, the transfer apparatus 100 described herein may have more or fewer components than those listed above.

First, the plurality of micro devices 110 include micro devices 110R, 110G, and 110B that respectively display red (R), green (G), and blue (B). The plurality of micro devices 100 are adhered to a transfer sheet using an adhesive, and the red micro devices 110R, the green micro devices 110G, and the blue micro devices 110B are sequentially arranged, and each of the micro devices 110R, 110G, and 110B may be disposed at equal intervals.

In addition, depending on the embodiment, the red micro devices 110R, the green micro devices 110G, and the blue micro devices 110B may be disposed at regular intervals, and the plurality of red, green, and blue micro devices may be sequentially arranged in an order of red, green, and blue, or may be arranged in a random order.

In addition, depending on the embodiment, only red micro devices 110R arranged at regular intervals may be transferred to the target substrate 120, only green micro devices 110G arranged at regular intervals may be transferred to the target substrate 120, and only blue micro devices 110B arranged at regular intervals may be transferred to the target substrate 120. Furthermore, only red micro devices 110R and green micro devices 110G may be arranged, only green micro devices 110G and blue micro devices 110B may be arranged, and only red micro devices 110R and blue micro devices 110B may be arranged. The transfer device 100 may transfer a plurality of micro devices 110 to the target substrate 120, and the target substrate 120 may be implemented as a printed circuit board (PCB), may be implemented as a glass type or thin film transistor (TFT) type through which a laser beam to be described below can pass, and may be implemented as sapphire or quartz (crystal). However, the embodiments are not limited thereto.

The target substrate 120 may include circuits corresponding to the red micro devices 110R, green micro devices 110G, and blue micro devices 110B being transferred. That is, power may be connected in common to regions to which negative power is applied, and power may be individually connected to regions to which positive power is applied.

The plurality of micro devices 110 may be transferred to the target substrate 120 through an adhesive. The adhesive may include components such as tin (Sn), silver (Ag), and gold (Au), but the embodiments are not limited thereto. The adhesive may be melted at 225 degrees Celsius, but the temperature may vary depending on the components of the adhesive.

In order to transfer the plurality of micro devices 110 to the target substrate 120, the aligner 130 may adjust the alignment of the plurality of micro devices 110 and the target substrate 120, and change transfer positions of the plurality of micro devices 110 and the target substrate 120.

The laser beam emitter 140 may be disposed above the transfer sheet and may emit beams having a specific wavelength in the direction passing through the transfer sheet. The laser beam emitter 140 may at one time emit beams with a width of 150 mm. However, there may be a difference in the width depending on the implementation of the laser beam emitter 140. One laser beam emitter 140 may transfer approximately 10,000 micro devices to the target substrate 120 simultaneously, but depending on the size of the micro devices there may be a difference in the number of micro devices transferred.

In addition, the laser beam emitter 140 may emit beams in various wavelength ranges, and, for example, may emit lasers having wavelengths of 915 nm, 950 nm and 980 nm, and wavelengths of 1400 nm or greater.

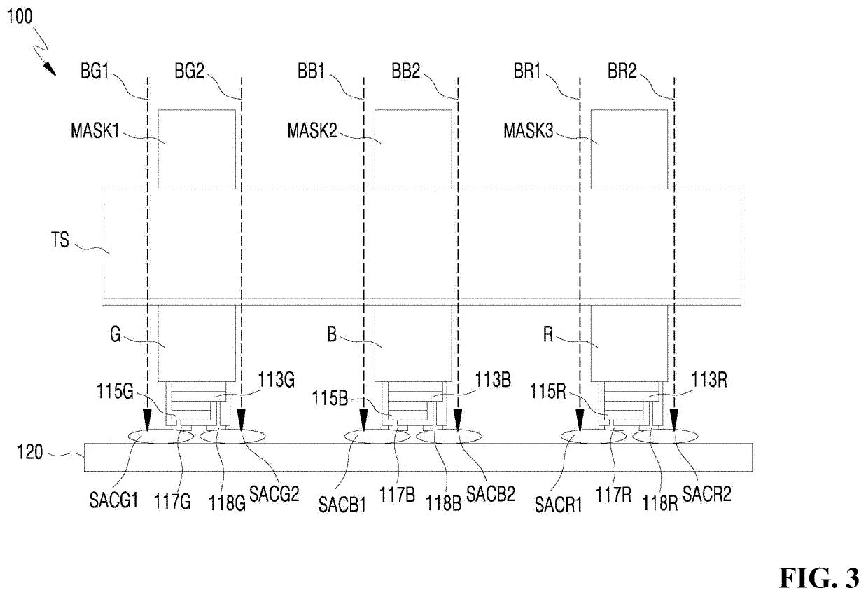

The laser beam emitter 140 may transfer the plurality of micro devices 110 to the target substrate 120 by melting an adhesive between the plurality of micro devices 110 and the target substrate 120. A method of performing the transfer by melting the adhesive using the laser beam emitter 140 will be described in FIGS. 3 to 5, and description thereof will thus be omitted here.

When the micro devices are arranged in a plurality of rows and a plurality of columns, the laser beam emitter 140 may move in the column direction while applying energy to the adhesive so that the micro devices are transferred to the target substrate, as a single row or as a plurality of rows, from the first row to the last row. That is, the laser beam emitter 140 may move in the column direction while simultaneously transferring one row or a plurality of rows, from the first row to the last row.

In another embodiment, the laser beam emitter 140 may apply energy to the adhesive such that micro devices not only in row units but also in one area unit are simultaneously transferred to the target substrate.

Once transfer of the plurality of micro devices 110 to the target substrate 120 is completed, the transfer sheet remover 150 may separate the transfer sheet and the plurality of micro devices 110. Since the plurality of micro devices 110 have been transferred to the target substrate 120, the transfer sheet and the adhesive can be easily separated from the plurality of micro devices 110. If the above method is used, the defect rate is significantly lower than that of a soldering method, in which the chip finely moves due to hot air or which does not guarantee constant transfer efficiency. In addition, area transfer of an area of 5 cm² or more per second can be performed simultaneously.

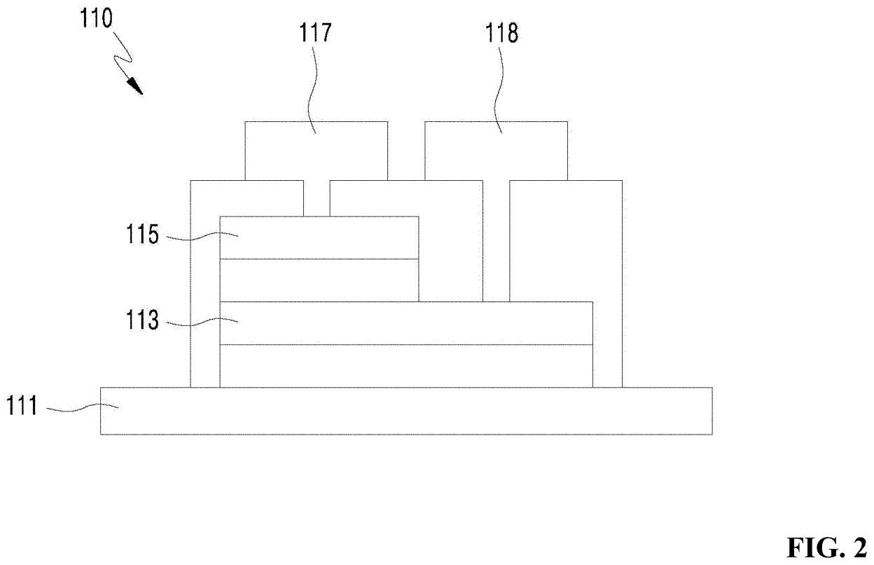

Hereinafter, the constituent layers of each of the micro devices 110 described above will be described with reference to FIG. 2. FIG. 2 is a reference diagram illustrating each layer of the micro devices. However, the embodiments are not limited to the illustrated layers, and other layers may be applied depending on the implementation example.

Referring to FIG. 2, each of the micro devices 110 includes a growth substrate 111, a first semiconductor layer 113, a second semiconductor layer 115, a first electrode 118, and a second electrode 117.

The growth substrate 111 may be implemented by, for example, sapphire, silicon carbide (SiC), gallium arsenide (GaAs), glass, quartz, or the like. Impurities on the surface of the growth substrate 111 may be removed by wet cleaning or plasma treatment.

The first semiconductor layer 113 and the second semiconductor layer 115 may be disposed on the growth substrate 111, and the first semiconductor layer 113 and the second semiconductor layer 115 may include at least one of gallium (Ga), nitrogen (N), indium (In), aluminum (Al), arsenic (As), or phosphorus (P), and may be formed of any one or more of gallium nitride (GaN), indium nitride (InN), aluminum nitride (AlN), indium gallium nitride (InGaN), aluminum gallium nitride (AlGaN), and indium gallium phosphide (InGaP).

However, when the micro device is a red micro device, the second semiconductor layer may be formed of GaAs or InGaP, and when the micro device is a green or blue micro device, the second semiconductor layer may be formed of GaN.

A conductive layer, an active layer, and the like may be further included between the semiconductor layers, and various semiconductor layers, buffer layers, and the like for forming micro LEDs and mini LEDs may be further included.

The first electrode (pad) 118 may be disposed on the first semiconductor layer 113 and the second electrode 117 may be disposed on the second semiconductor layer 115, and the first electrode 118 and the second electrode 117 may include at least one of molybdenum (Mo), chromium (Cr), nickel (Ni), gold (Au), aluminum (Al), titanium (Ti), platinum (Pt), vanadium (V), tungsten (W), lead (Pd), tin (Sn), copper (Cu), rhodium (Rh), or iridium (Ir), in a single layer or multilayer structure.

The adhesive (adhesive material) may be disposed on the first electrode 118 and the second electrode 117, and used in transferring the micro devices 110 to the target substrate 120. Examples of the adhesive may include AuSn, AuNi, Au, In, Sn, SAC305, anisotropic conductive paste (ACP), and anisotropic conductive film (ACF), but the embodiments are not limited thereto. Here, the material such as AuSn, AuNi, Sn, In, or the like may be formed by a plating method. Hereinafter, transfer methods of an apparatus for simultaneously transferring micro devices to a target object according to various embodiments of the present disclosure will be described with reference to FIGS. 3 to 5. In the description, the reference numerals in FIGS. 1 and 2 will be referred to.

According to FIG. 3, a transfer sheet TS may be provided. A green micro device G, a blue micro device B, and a red micro device R may be adhered to the lower portion of the transfer sheet TS. On top of the transfer sheet TS, masks (MASK 1 to 3) may be provided to align with the green micro device G, the blue micro device B, and the red micro device R. The masks MASK 1 to 3 may be masks used in general semiconductor processes. Instead of the transfer sheet TS, a sapphire substrate or quartz (crystal) may be applied, but the embodiments are not limited thereto.

When the transfer positions of the green micro device G, the blue micro device B, and the red micro device R have been aligned with the target substrate by the aligner 130, the laser beam emitter 140 may emit beams.

The laser beam emitter 140 may emit beams downward, in a direction toward the lower portion of the transfer sheet TS (BG1, BG2, BB1, BB2, BR1, and BR2). The beams of the laser beam emitter 140 are uniformly emitted in the downward direction, but due to the masks MASK 1 to 3, the beams may not be emitted onto the green micro device G, the blue micro device B, and the red micro device R. Accordingly, the laser beam emitter 140 may melt the adhesives (SACG1, SACG2, SACB1, SACB2, SACR1, SACR2) so as to transfer the green micro device G, the blue micro device B, and the red micro device to the target substrate 120. According to the above method, transfer can be performed while the micro devices and the target substrate 120 are fixed, and the transfer yield can accordingly be improved in comparison to existing methods.

According to FIG. 3, due to the masks MASK 1 to 3, the beams are not emitted onto the green micro device (G), the blue micro device (B), and the red micro device (R). The beams of the laser beam emitter 140 do not pass through the plurality of micro devices R, G, B, but the adhesive material around the first and second pads 117G, 118G, 117B, 118B, 117R, 118R of the plurality of micro devices is melted so as to transfer the micro devices R, G, and B to the target substrate 120.

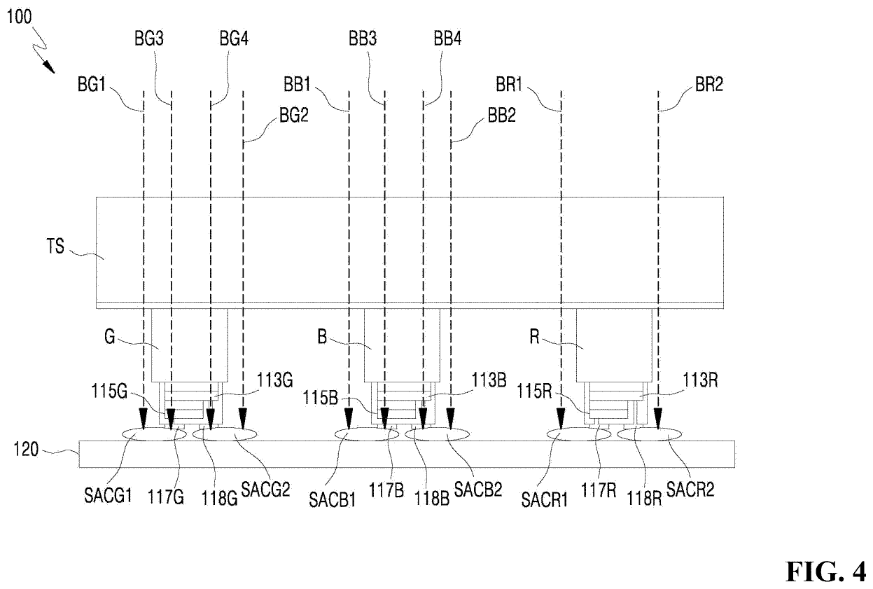

Referring to FIG. 4, the laser beam emitter 140 may emit beams having wavelengths of 915 nm, 950 nm, and 980 nm in the direction toward the transfer sheet. The laser beam emitter 140 may emit beams in a wavelength range that can pass through the green micro device G and the blue micro device B, and the beams can thus pass through the green micro device G and the blue micro device B and melt the adhesives SACG1, SACG2, SACB1, SACB2, SACR1, and SACR2, thereby adhering the micro devices G and B to the target substrate 120. If the wavelength of the beam of the laser beam emitter 140 exceeds 900 nm, the transmittance may be 80% or greater.

Further, in the case of the red micro device R, the laser beam emitter 140 may melt the adhesive material around the electrodes 117R and 118R in the same manner as in FIG. 3, so as to transfer the red micro device R to the target substrate 120. This is because beams having a wavelength of 915 nm, 950 nm, and 980 nm have a low transmittance for GaAs and InGaP materials.

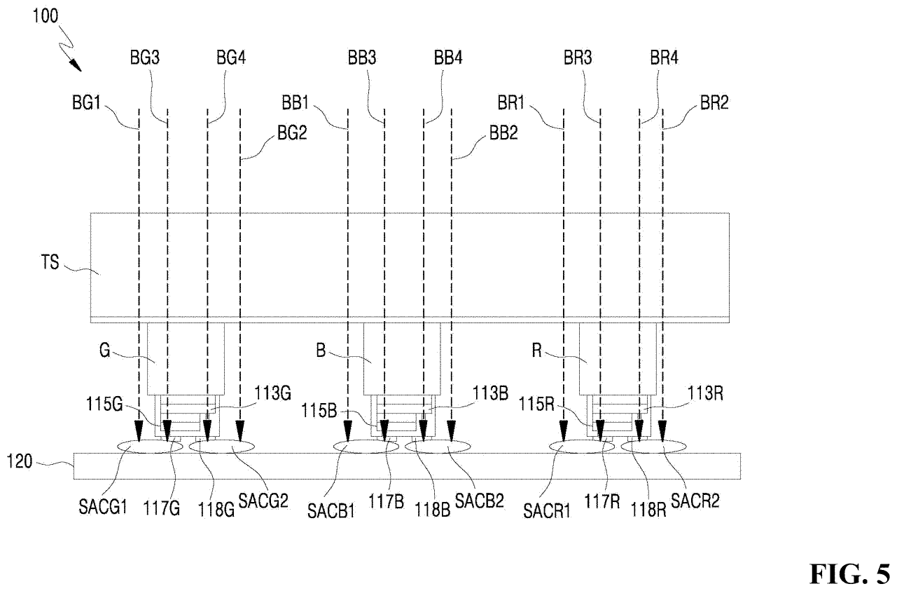

Referring to FIG. 5, the laser beam emitter 140 may emit beams in a wavelength range of 1400 nm or greater, capable of passing through all of the plurality of micro devices R, G, and B, in the direction toward the transfer sheet TS. A beam having a wavelength in this wavelength range can also pass through the red micro device R.

The transfer apparatuses 100 illustrated in FIGS. 3 to 5 may perform a transfer operation at a working temperature of 150 to 220 degrees Celsius. This is because, when the melting temperature of the adhesive is 225 degrees Celsius, a working temperature of 150 to 220 degrees can allow for easy adhesion both without requiring application of high power from the laser beam emitter 140 and without melting the adhesive. However, when the adhesive is composed of an AuSn layer and an Au/Ag layer, a flux layer may be additionally provided so that the transfer process may be performed at a lower temperature. In addition, when the adhesive is composed of ACF, transfer may be performed by a pressing and hot plating method, and when the adhesive is ACP, the adhesive may be melted in a reflow process.

In addition, depending on the embodiment, when a material such as AuSn, AuNi, Sn, or In is disposed on the first pad and the second pad using a plating method, there is no particular need for an adhesive to be disposed on the target substrate 120, since such materials act as an adhesive.

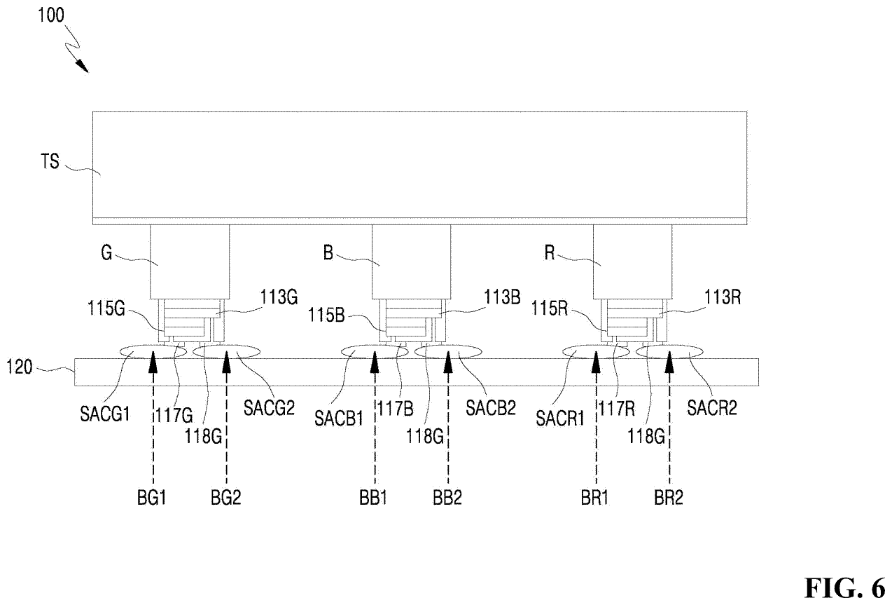

FIG. 6 illustrates a transfer apparatus 100 in which laser beams are emitted from a different direction, according to another embodiment of the present disclosure.

The laser beam emitter 140 in this embodiment may not emit beams in the manner illustrated in FIGS. 3 to 5, and may instead emit beams in a direction penetrating the target substrate 120 from below the target substrate 120. The wavelengths of these laser beams may be applied to be the same as when emitted from above the target substrate 120.

In this case, the target substrate 120 is formed as a glass type or a TFT type, so that the adhesives SACG1, SACG2, SACB1, SACB2, SACR1, and SACR2 may be melted and the target substrate 120 and the micro devices can be bonded to each other. Further, when, as the adhesive, a material such as AuSn, AuNi, Sn, or In is disposed on the first pad and the second pad by a plating method, adhesion may occur without the need for an adhesive.

The arrangement of micro devices adhered to the target substrate 120 may include red, green, and blue micro devices arranged in sequence, red, green, and blue micro devices arranged randomly, arrangement of micro devices composed only of red micro devices, arrangement of micro devices composed only of green micro devices, arrangement of micro devices composed only of blue micro devices, and arrangement of micro devices composed only of two types of micro device (for example, R/G, G/B, B/R).

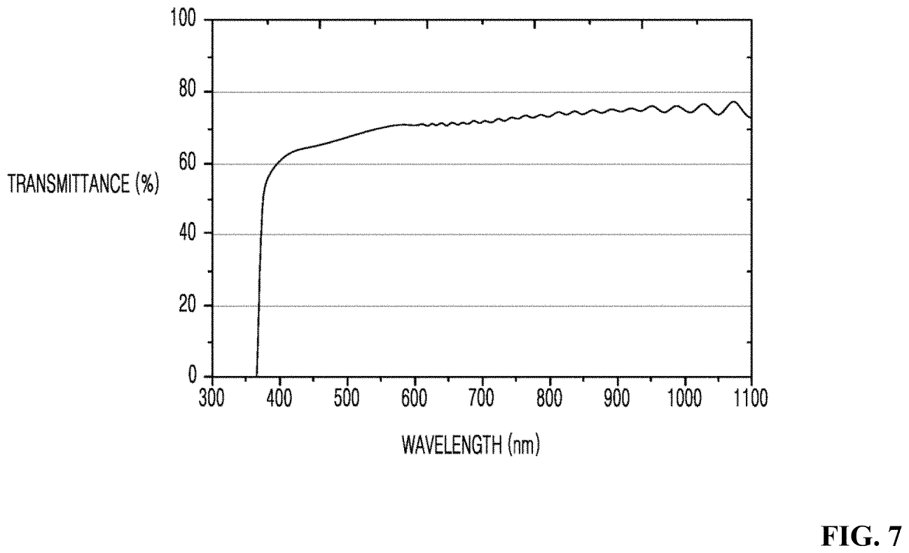

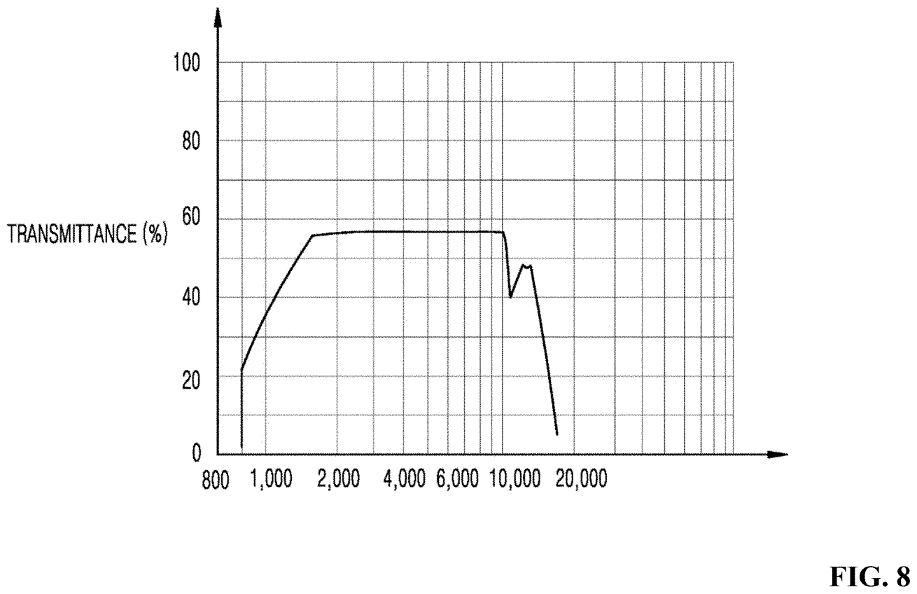

FIG. 7 shows transmittance of a laser beam with respect to GaN, and FIG. 8 shows the transmittance of the laser beam with respect to GaAs.

GaN can be applied to a green or blue micro device, and the transmittance may exceed 80% at wavelengths of 900 nm or greater. Accordingly, the beams of the laser beam emitter 140 can easily pass through GaN and melt the adhesive.

GaAs can be applied to a red micro device, and the transmittance can be 50% or higher at wavelengths of 1400 nm or greater. Accordingly, the beams of the laser beam emitter 140 can easily pass through each semiconductor layer of the red micro device and melt the adhesive.

Although the present specification includes details of multiple specific implementations, these should not be construed as limiting the present disclosure to an invention or scope of claim, but are rather to be understood as a description of features that may be particular to a specific embodiment of a specific implementation of the present disclosure. Similarly, specific features described herein in the context of individual embodiments may be implemented in combination in a single embodiment. Conversely, various features described in the context of a single embodiment may also be implemented individually or in any suitable sub-combination in a plurality of embodiments. Furthermore, although features operate in specific combinations and may initially be described as though claimed as such, one or more features from a claimed combination may in some cases be excluded from the combination, and the claimed combination may be changed to a sub-combination or variations of a sub-combination.

In addition, although the present specification describes the operations in the drawings in a specific order, it is not to be understood that such operations must be performed in the illustrated specified order or sequential order, or that all illustrated operations must be performed, in order to obtain desirable results. In specific cases, one or a plurality of devices can be transferred simultaneously.

As such, the present specification is not intended to limit the present disclosure to the specific terms presented herein. Accordingly, although the present disclosure has been described in detail with reference to the above-described examples, those skilled in the art can make modifications, changes, and modifications to these examples without departing from the scope of the present disclosure. The scope of the present disclosure is defined by the following claims rather than the above detailed description, and all changes and modifications obtained from the meaning and range of claims and equivalent concepts should be construed as being included in the scope of the present disclosure.

What is claimed is:

1. An apparatus for simultaneously transferring micro devices to a target object, the apparatus comprising:
a plurality of red, green, and blue micro devices adhered to a transfer sheet by an adhesive material;
a target substrate to which the micro devices are transferred;
an aligner configured to align the plurality of micro devices with the target substrate; and
a laser beam emitter disposed above the transfer sheet and configured to emit beams having a specific wavelength in a direction passing through the transfer sheet,
wherein the micro devices each comprise:
a growth substrate;
a first semiconductor layer and a second semiconductor layer, disposed on the growth substrate;
a first pad disposed on the first semiconductor layer and a second pad disposed on the second semiconductor layer; and
an adhesive material disposed on the first pad and the second pad, and
wherein when the micro devices and the target substrate have been aligned in transfer positions by the aligner, the laser beam emitter applies energy to the adhesive material so as to transfer the micro devices to the target substrate.

2. The apparatus of claim 1, wherein the adhesive material adhered to the first pad and the second pad of the micro devices is melted using beams having a specific wavelength that pass through all the micro devices, so as to transfer the micro devices to the target substrate.

3. The apparatus of claim 1,
wherein the adhesive material adhered to the first pad and the second pad of the plurality of green and blue micro devices device is melted using beams having a specific wavelength that pass through green and blue micro devices, and
wherein, in the case of the red micro devices, the adhesive material around pads of the red micro devices is melted, so as to transfer the R micro devices to the target substrate.

4. The apparatus of claim 1, further comprising masks respectively disposed on the transfer sheet at regions aligned with the plurality of micro devices,
wherein beams of the laser beam emitter do not pass through the plurality of micro devices, but melt the adhesive material around the first pad and the second pad of the plurality of micro devices so as to transfer the micro devices to the target substrate.

5. The apparatus of claim 2, wherein a wavelength of the beams having a specific wavelength is 1400 nm.

6. The apparatus of claim 3, wherein a wavelength of the beams having a specific wavelength is at least one of 915 nm, 950 nm, or 980 nm.

7. The apparatus of claim 1, wherein an ambient temperature of a place where the apparatus is driven is in a range of 150 degrees Celsius to 220 degrees Celsius.

8. The apparatus of claim 1, wherein when the micro devices are arranged in a plurality of rows and a plurality of columns, the laser beam emitter moves in a column direction while simultaneously transferring one row or a plurality of rows of micro devices to the target substrate, from a first row to a last row.

9. The apparatus of claim 1,
wherein the plurality of red, green, and blue micro devices are disposed at regular intervals, and
wherein the plurality of red, green, and blue micro devices are sequentially arranged in an order of red, green, and blue, or are arranged in a random order.

10. An apparatus for simultaneously transferring micro devices to a target object, the apparatus comprising:
a plurality of micro devices adhered to a transfer sheet by an adhesive material;
a target substrate to which the micro devices are transferred;
an aligner configured to align the plurality of micro devices with the target substrate; and
a laser beam emitter disposed above the transfer sheet and configured to emit beams having a specific wavelength in a direction passing through the transfer sheet,
wherein the micro devices each comprise:
a growth substrate;
a first semiconductor layer and a second semiconductor layer, disposed on the growth substrate;
a first pad disposed on the first semiconductor layer and a second pad disposed on the second semiconductor layer; and
an adhesive material disposed on the first pad and the second pad,
wherein when the micro devices and the target substrate have been aligned in transfer positions by the aligner, the laser beam emitter applies energy to the adhesive material so as to transfer the micro devices to the target substrate, and
wherein the plurality of micro devices are composed of only one type among red micro devices, green micro devices, and blue micro devices.

11. An apparatus for simultaneously transferring micro devices to a target object, the apparatus comprising:
a plurality of red, green, and blue micro devices adhered to a transfer sheet by an adhesive material;
a target substrate, wherein the micro devices are transferred to one surface of the target substrate;
an aligner configured to align the plurality of micro devices with the target substrate; and
a laser beam emitter configured to emit beams having a specific wavelength in a direction passing through the transfer sheet from the other surface of the target substrate,
wherein the micro devices each comprise:
a growth substrate;
a first semiconductor layer and a second semiconductor layer, disposed on the growth substrate;
a first pad disposed on the first semiconductor layer and a second pad disposed on the second semiconductor layer; and
an adhesive material disposed on the first pad and the second pad,
wherein when the micro devices and the target substrate have been aligned in transfer positions by the aligner, the laser beam emitter applies energy to the adhesive material so as to transfer the micro devices to the target substrate.
